(19) United States
(12) Patent Application Publication
(10) Pub. No.: US 2025/0355941 A1
(43) Pub. Date: Nov. 20, 2025

(54) ELECTRONIC DEVICE AND OPERATION METHOD THEREOF

(71) Applicant: SAMSUNG ELECTRONICS CO., LTD., Suwon-si (KR)

(72) Inventors: SANGYEON KIM, Suwon-si (KR); HYUNWOO PARK, Seoul (KR); JINWOO CHOI, Seoul (KR); YEEUN CHOI, Seoul (KR); SEHYEON KIM, Suwon-si (KR); CHUNGGYEOM KIM, Suwon-si (KR); YOUNGBIN PARK, Suwon-si (KR); HEEWON LEE, Suwon-si (KR)

(73) Assignee: SAMSUNG ELECTRONICS CO., LTD., Suwon-si (KR)

(21) Appl. No.: 19/173,317

(22) Filed: Apr. 8, 2025

(30) Foreign Application Priority Data
May 17, 2024 (KR) 10-2024-0059917

(51) Int. Cl. G06F 16/901

(52) U.S. Cl. CPC G06F 16/9024

(57) ABSTRACT

An electronic device includes at least one memory and at least one processor configured to execute at least one instruction stored in the at least one memory. The at least one processor, by executing the at least one instruction, may output a first shortest path number, defined by a source node, a pass node, and a target node among a plurality of nodes to which a plurality of ports are connected, and a second shortest path number, defined by the source node and the target node, and calculate a first betweenness centrality (BC) value for the plurality of nodes based on summing first pair-dependency values for respective pairs of the source node and the target node. A first pair-dependency value is defined as a product of a second pair-dependency value, a number of ports connected to the source node, and a number of ports connected to the target node.

### CROSS-REFERENCE TO RELATED APPLICATION(S)

This U.S. non-provisional application is based on and claims priority under 35 USC § 119 to Korean Patent Application No. 10-2024-0059917, filed on May 7, 2024, in the Korean Intellectual Property Office, the disclosure of which is herein incorporated by reference in its entirety.

### BACKGROUND

One or more example embodiments relate to an electronic device and an operation method of the electronic device. In particular, one or more example embodiments relate to an electronic device for calculating betweenness centrality (BC) considering a port in a node-port structure and an operation method of the electronic device

A semiconductor wafer manufacturing process includes a plurality of complex processes and is controlled by an automated material handling system (AHMS). Wafers, on which chips are manufactured, are transported by containers (or carriers), which are called front opening unified pods (FOUPs), and the FOUPs may be transported between machines by overhead hoist transports (OHTs). Due to various factors (for example, an intersection type, a speed limit, or the like) on a railway network formed by a plurality of OHTs, a method of preventing congestion in the railway network may be required.

### SUMMARY

One or more example embodiments provide an electronic device for calculating betweenness centrality (BC) considering a port in a node-port structure and an operation method of the electronic device.

According to an example embodiment, an electronic device includes a memory configured to store at least one instruction and at least one processor configured to execute the at least one instruction. The at least one processor, by executing the at least one instruction, may output a first shortest path number, defined by a source node, a pass node, and a target node among a plurality of nodes to which a plurality of ports are connected, and a second shortest path number, defined by the source node and the target node, based on performing a shortest path calculation algorithm on the plurality of nodes and the plurality of links connecting the plurality of nodes, and may calculate a first betweenness centrality (BC) value for the plurality of nodes based on summing first pair-dependency values for respective pairs of the source node and the target node among the plurality of nodes. A first pair-dependency value is defined as a product of a second pair-dependency value defined as a ratio of the first shortest path number to the second shortest path number, a first port number defined as a number of ports connected to the source node among the plurality of ports, and a second port number defined as a number of ports connected to the target node among the plurality of ports.

According to an example embodiment, an operation method includes outputting a first shortest path number defined as a source node, a pass node, and a target node, among a plurality of nodes to which a plurality of ports are connected, and a second shortest path number defined based on the source node and the target node, based on performing a shortest path calculation algorithm on the plurality of nodes and a plurality of links connecting the plurality of nodes, and calculating a first betweenness centrality (BC) value for the plurality of nodes based on summing first pair-dependency values for respective pairs of the source node and the target node among the plurality of nodes, a first pair-dependency value being defined as a product of a second pair-dependency value defined as a ratio of the first shortest path number to the second shortest path number, a first port number defined as a number of ports connected to the source node among the plurality of ports, and a second port number defined as a number of ports connected to the target node among the plurality of ports.

According to an example embodiment, an electronic device includes a shortest path calculation circuit configured to output a first shortest path number defined as a source node, a pass node, and a target node, among a plurality of nodes to which a plurality of ports are connected, and a second shortest path number defined based on the source node and the target node, based on performing a shortest path calculation algorithm on the plurality of nodes and a plurality of links connecting the plurality of nodes, and a BC calculation circuit configured to calculate a first betweenness centrality (BC) value for the plurality of nodes based on summing first pair-dependency values for respective pairs of the source node and the target node among the plurality of nodes, a first pair-dependency value being defined as a product of a second pair-dependency value defined as a ratio of the first shortest path number to the second shortest path number, a first port number defined as a number of ports connected to the source node among the plurality of ports, and a second port number defined as a number of ports connected to the target node among the plurality of ports.

### BRIEF DESCRIPTION OF DRAWINGS

Example embodiments will be more clearly understood from the following detailed description taken in conjunction with the accompanying drawings.

FIG. 1 is a block diagram of an electronic device according to one or more example embodiments.

FIG. 2 is a diagram illustrating a node-port structure according to one or more example embodiments.

FIG. 3 is a flowchart illustrating a method of operating an electronic device according to one or more example embodiments.

FIG. 4 is a block diagram of an electronic device according to one or more example embodiments.

FIG. 5 is a flowchart illustrating a method of calculating a betweenness centrality (BC) value of an electronic device according to one or more example embodiments.

FIG. 6 is a flowchart illustrating a method of calculating a BC value of an electronic device according to one or more example embodiments.

FIG. 7 is a graph illustrating a comparison between computation times of BC calculation according to one or more example embodiments.

FIG. 8 is a block diagram of an electronic device according to one or more example embodiments, and FIG. 9 is a diagram illustrating a computation time of the electronic device of FIG. 8.

FIG. 10 is a block diagram of an electronic device according to one or more example embodiments.

FIG. 11 is a diagram illustrating visualization data considering only a node for a node-port structure according to one or more example embodiments.

FIG. 12 is a diagram illustrating visualization data considering both a node and a port for a node-port structure according to one or more example embodiments.

FIG. 13 is a block diagram of an electronic device according to one or more example embodiments.

FIG. 14 is a block diagram of an electronic device according to one or more example embodiments.

FIG. 15 is a flowchart illustrating a method of operating an electronic device according to one or more example embodiments.

FIG. 16 is a flowchart illustrating a method for visualizing an electronic device according to one or more example embodiments.

### DETAILED DESCRIPTION

Hereinafter, example embodiments will be described with reference to the accompanying drawings.

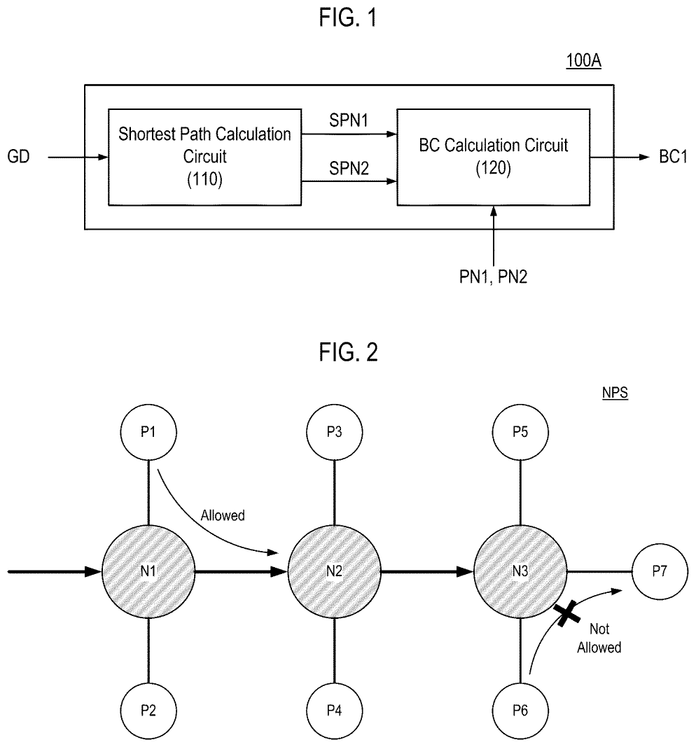

FIG. 1. 1 is a block diagram of an electronic device according to one or more example embodiments, and FIG. 2 is a diagram illustrating a node-port structure according to one or more example embodiments.

Referring to FIG. 1, an electronic device 100A according to one or more example embodiments may be configured to calculate a betweenness centrality (BC) value in a node structure and/or a node-port structure. The BC value may be defined as an indicator identifying connectivity between nodes or links in a network structure including a plurality of nodes and a plurality of links (or edges) between the nodes. The BC value may be used to identify a bridge and/or a bottleneck in the network structure.

The electronic device 100A according to one or more example embodiments may calculate the above-mentioned BC value in, for example, the node-port structure.

Referring to FIG. 2, a node-port structure NPS may include a plurality of ports in addition to a node structure including a plurality of nodes and a plurality of links defined between two nodes among the plurality of nodes. A port may be mapped to a closest node, and a plurality of ports may be mapped to a single node. For example, a first port P1 and a second port P2 may be connected to a first node N1, a third port P3 and a fourth port P4 may be connected to a second node N2, and a fifth port P5, a sixth port P6, and a seventh port P7 may be connected to a third node N3. A path between a single node and another single node and a path between a single node and a single port may both be defined as a link.

According to one or more example embodiments, when the node-port structure NPS is a railway network, each of the plurality of nodes may include a sensor to sense an overhead hoist transport (OHT) device. In addition, each of the plurality of ports may be configured to accommodate a container transported through the OHT device. For example, the plurality of nodes may sense a location and/or a speed of the OHT device.

The electronic device 100A according to one or more example embodiments may be used in an OHT control system operator that collects and analyzes data to determine a vulnerable section of an OHT railway. The electronic device 100A may calculate the BC value without considering a path from a port to another port for the same node in the node-port structure NPS. For example, when the BC value is calculated, a path from the first port P1 to the first node N1 and then to the second node N2 may be taken into consideration, but a path from the sixth port P6 to the third node N3 and then to the seventh port P7 may not be taken into consideration. This is because there is little movement between ports for the same node in the node-port structure NPS, and a path between ports for the same node does not affect BC calculation of another link.

Returning back to FIG. 1, the electronic device 100A may include a shortest path calculation circuit 110 and a BC calculation circuit 120 to calculate the BC value in a node structure and/or a node-port structure.

The shortest path calculation circuit 110 may perform a shortest path calculation algorithm on graph data GD including a plurality of nodes to which a plurality of ports are connected and a plurality of links defined between two nodes, among the plurality of nodes. The shortest path calculation algorithm may also be referred to as a single source shortest path (SSSP). For example, the shortest path calculation algorithm (or SSSP algorithm) may include a breadth first search (BFS) algorithm, a Dijkstra algorithm, or the like.

The shortest path calculation circuit 110 may output a first shortest path count SPN1 and a second shortest path count SPN2 through the shortest path calculation algorithm. The first shortest path count SPN1 may be a number of shortest paths defined based on a source node, a pass node, and a target node among the plurality of nodes, and the second shortest path count SPN2 may be a number of shortest paths defined based on the source node and target node. The source node may be a departure point, the target node may be a destination, and the pass node may be an intermediate node between the source node and the target node.

The shortest path calculation circuit 110 may perform the shortest path calculation algorithm while changing the source node in the plurality of nodes. For example, the shortest path calculation circuit 110 may calculate a shortest path through a series of operations including an operation of adding a node, which is closest to an already discovered node set, as the source node.

The BC calculation circuit 120 may calculate the BC value based on the first shortest path count SPN1 and the second shortest path count SPN2 output from the shortest path calculation circuit 110. According to one or more example embodiments, the BC calculation circuit 120 may calculate a first BC value BC1 for the plurality of nodes based on summing first pair-dependency values for the plurality of nodes. A pair-dependency value may be defined as a variable representing a dependency between an arbitrary node and another node.

According to one or more example embodiments, the first pair-dependency value may be defined as a product of a second pair-dependency value defined as a ratio of the first shortest path count SPN1 to the second shortest path count SPN2, a first port number PN1 defined as a number of ports, connected to the source node, among the plurality of ports, and a second port number PN2 defined as a number of ports, connected to the target node, among the plurality of ports. The second pair-dependency value may be used to calculate a BC value in the node structure. For example, the BC calculation circuit 120 according to one or more example embodiments may use the first port number PN1 and the second port number PN2 for BC calculation to take an added port in the node-port structure into consideration for the BC calculation.

In a node-port structure such as the above-described railway network, an actual departure point or destination is a port rather than a node. In the related art, port information cannot be considered at all as the BC calculation algorithm is applied to the node structure. The BC calculation circuit 120 according to one or more example embodiments may perform accurate BC calculation even in a node-port structure by additionally taking a number of ports into consideration in addition to the second pair-dependency value.

According to one or more example embodiments, the BC calculation circuit 120 may sum first pair-dependency values for respective pairs of the source node and the target node among the plurality of nodes by accumulating a BC value from a farthest node to the source node along predecessor nodes. The accumulation may allow the BC calculation circuit 120 to reduce the time and space complexity for BC calculation.

The electronic device 100A according to the above-described embodiments may calculate a BC value by considering ports not only in the node structure but also in the node-port structure. Accordingly, the BC value may be accurately calculated in the node-port structure, and vulnerable sections in the node-port structure may be detected more accurately.

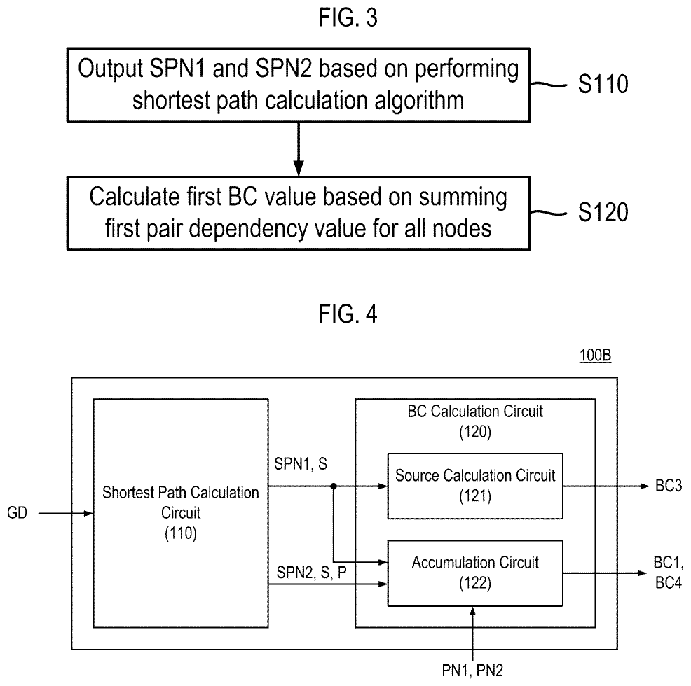

FIG. 3 is a flowchart illustrating a method of operating an electronic device according to one or more example embodiments.

Referring to FIG. 3, in operation S110, an electronic device may output a first shortest path number SPN1 and a second shortest path number SPN2 based on performing a shortest path calculation algorithm for a plurality of nodes and a plurality of links.

In operation S120, the electronic device may calculate a first BC value based on summing first pair-dependency values for the plurality of nodes. The first pair-dependency value may be obtained by multiplying a second pair-dependency value defined as a ratio of the first shortest path number SPN1 and the second shortest path number SPN2 output in operation S110, the number of first ports, and the number of second ports.

Accordingly, the electronic device may calculate the BC value (hereinafter, may be referred to as the first BC value) by considering ports even in a node-port structure. Hereinafter, a BC value calculation operation of the electronic device will be described in more detail.

A BC value for a node structure (hereinafter referred to as a second BC value) may be calculated based on the following Equation 1.

$$BC ( v ) = {\sum }_{s \neq v \neq t ∈ V} \frac{{σ}_{st} ( v )}{{σ}_{st}} = {\sum }_{s \neq v \neq t ∈ V} {δ}_{st} ( v ) \qquad Equation 1$$

where σₛₜ(v) is the number of shortest paths that reach a target node t via a node v from a source node s, σₛₜ is the number of shortest paths that reach the target node t from the source node s, and δₛₜ(v) is a pair-dependency value, which may be defined as

$$\frac{{σ}_{st} ( v )}{{σ}_{st}} .$$

σₛₜ(v) is the number of the above-mentioned first shortest paths, σₛₜ is the number of the above-mentioned second shortest paths, and σₛₜ(v) is the above-mentioned second pair-dependency value. As can be seen from Equation 1, the second pair-dependency value is a value that is obtained without considering ports. According to one or more example embodiments, the electronic device may calculate the first BC value based on Equation 2.

$${BC}_{p} ( v ) = {\sum }_{s \neq v \neq t ∈ V} \frac{{σ}_{st} ( v )}{{σ}_{st}} p ( s ) p ( t ) = {\sum }_{s \neq v \neq t ∈ V} {δ}_{st , p} ( v ) \qquad Equation 2$$

where p(s) is the number of ports for the source node s, which is the number of the above-mentioned first port, and p(t) is the number of ports for the target node t, which is the number of the above-mentioned second ports. δ_{st,p}(v) is a pair-dependency value modified according to the node-port structure, which may be defined as

$$\frac{{σ}_{st} ( v )}{{σ}_{st}} p ( s ) p ( t ) .$$

For example, δ_{st,p}(v) is the above-mentioned first pair-dependency value. V is a set of all nodes.

If the sum of all first pair-dependency values for all target nodes from a single source node to all target nodes is defined as δ_{s•,p}(v), then δ_{s•,p}(v) may be defined as Equation 3.

$${δ}_{s , p} ( v ) = {\sum }_{t ∈ V} {δ}_{st , p} ( v ) = {\sum }_{t ∈ V} {\sum }_{w : v ∈ {P}_{s} ( w )} {δ}_{st , p} ( v , \{ v , w \} ) = {\sum }_{w : v ∈ {P}_{s} ( w )} {\sum }_{t ∈ V} {δ}_{st , p} ( v , \{ v , w \} ) \qquad Equation 3$$

where node w is a successor node of node v, and Pₛ(w) is a set of predecessor nodes of node w, and w:vϵPₛ(w) refers to a set of the successor nodes w, each having node v as a predecessor node on the shortest path including node v. In addition, δ_{st,p}(v, {v,w}) is a pair-dependency value in the node-port structure passing through node v and link {v, w}. δ_{st,p}(v, {v, w}) may be further defined as Equation 4.

$${δ}_{st , p} ( v , \{ v , w \} ) = \{ \begin{matrix}\frac{σ \text{?}}{σ \text{?}} \cdot p ( s ) p ( w ) & if t = w \\ \begin{matrix}\frac{{σ}_{sw} ( v \text{?} ( v \text{?} w \text{?} \cdot σ \text{?}}{{σ}_{st}} \cdot p ( s ) p ( t ) = \\ \frac{σ \text{?}}{σ \text{?}} \cdot \frac{σ \text{?} ( w )}{σ \text{?}} \cdot p ( s ) p ( t )\end{matrix} & if t \neq w\end{matrix} \qquad Equation 4$$

$$\text{?} \text{indicates text missing or illegible when filed}$$

If t=w (for example, if a target node is successor w), then σ_{sw}(v, {v, w})=σₛᵥ. Therefore, from Equation 2, δ_{st,p}(v, {v, w}) may be defined as

$$\frac{{σ}_{sv}}{{σ}_{sw}} \cdot p ( s ) p ( w ) .$$

σ_{sw}(v, {v,w})=σₛᵥ is the number of shortest paths between source node s and successor w passing through node v and link {v, w}, σ_{sw}(v, {v, w})=σₛᵥ is the number of shortest paths between source node s and node v, σ_{sw}(v, {v, w})=σₛᵥ is the number of shortest paths between source node s and successor w, and p(w) is the number of ports for the successor.

If t is not w, then σₛₜ(v, {v, w})=σ_{sw}(v, {v, w})·σ_{wt}. σₛₜ(w)=σ_{sw}·σ_{wt}, where σ_{wt} may be

$$\frac{{σ}_{st} ( w )}{{σ}_{sw}} .$$

Ultimately, δ_{st,p}(v, {v, w}) when t is not w may be defined as Equation 4, where σ_{wt} is the number of shortest paths between successor w and target node t.

Based on Equation 4, δ_{s•,p}(v) of Equation 3 may be redefined as Equation 5 or Equation 6.

$${\sum }_{w : v ∈ {P}_{s} ( w )} ( \frac{{σ}_{sv}}{{σ}_{sw}} \cdot p ( s ) p ( w ) + {\sum }_{t ∈ V ( w )} \frac{{σ}_{sv}}{{σ}_{sw}} \cdot \frac{{σ}_{st} ( w )}{{σ}_{st}} \cdot p ( s ) p ( t ) ) \qquad Equation 5$$

$${\sum }_{w : v ∈ {P}_{s} ( w )} \frac{{σ}_{sv}}{{σ}_{sw}} \cdot ( p ( s ) p ( w ) + {δ}_{s , p} ( w ) ) \qquad Equation 6$$

In Equation 6, δ_{s•,p}(w) is the same as

$${\sum }_{t ∈ V ( w )} \frac{{σ}_{sv}}{{σ}_{sw}} \cdot \frac{{σ}_{st} ( w )}{{σ}_{st}} \cdot p ( s ) p ( t )$$

in Equation 5. As a result, Equation 6 refers to recursively calculating δ_{s•,p}(v) from successor w in the node-port structure. For example, the first pair-dependency value δ_{s•,p}(w) for successor node w is updated as node v to be calculated changes towards source node s. Ports may be regarded as additional nodes in the node-port structure, and thus, the number of nodes and links in BC calculation may increase. As a result, time complexity of BC calculation in the node-port structure may increase. The electronic device according to one or more example embodiments may calculate a first BC value through pair-dependency accumulation to maintain a calculation time even when ports are additionally taken into consideration.

According to the described embodiments, the electronic device may calculate the first BC value in the node-port structure based on Equation 6. The first BC value defined in Equation 2 may be calculated through Equation 6. For example, the electronic device may calculate the first BC value defined in Equation 2 by performing an operation of recursively accumulating a pair-dependency value from successor w.

FIG. 4 is a block diagram of an electronic device according to one or more example embodiments.

Referring to FIG. 4, an electronic device 100B according to one or more example embodiments may include a shortest path calculation circuit 110 and a BC calculation circuit 120, similar to the configuration illustrated in FIG. 1. The BC calculation circuit 120 may be configured to calculate a BC value based on Equation 6, and may include a source calculation circuit 121 and an accumulation circuit 122.

According to one or more example embodiments, the shortest path calculation circuit 110 may output a sequence set S and a predecessor node set P, together with a first shortest path number SPN1 and a second shortest path number SPN2, based on performing a shortest path calculation algorithm on graph data GD. The sequence set S may be defined as a node sequence for a target node from a source node, and the predecessor set P may be defined as a set of predecessors for a respective node in the sequence set S.

The shortest path calculation circuit 110 may output the first shortest path number SPN1 and the sequence set S to the source calculation circuit 121, and may output the second shortest path number SPN2, the sequence set S, and the predecessor node set P to the accumulation circuit 122.

The source calculation circuit 121 may be configured to calculate a BC value for the source node (hereinafter referred to as a third BC value BC3). The source calculation circuit 121 may check whether an arbitrary node included in the sequence set S is a source node.

When the arbitrary node is not the source node, the source calculation circuit 121 may output a sum port number. For example, the source calculation circuit 121 may output the sum port number based on performing accumulation of a number of third ports, defined as a number of ports connected to remaining nodes except for the source node among the plurality of nodes, on the remaining nodes. The following description may be provided based on an equation. The source calculation circuit 121 may perform sum_ports+=PN3 on nodes in the sequence set S, where sum_ports is a sum port number and PN3 is a third port number. The third port number may be obtained from the first port number (for example, the third port number is the number of ports obtained when a target node is an arbitrary node).

The source calculation circuit 121 may calculate the third BC value BC3 for the source node based on performing accumulation of a product of the sum port number and the first port number PN1 on the source node. The following description may be provided based on an equation. The source calculation circuit 121 may perform BC3+=PN1*sum_ports. As a result, according to the above-described embodiments, the source calculation circuit 121 may separately calculate the third BC value for the source node. This is because an actual departure point is not a source node itself, but is a port connected to the source node in the node-port structure.

The BC calculation circuit 120 may calculate a first BC value BC1 based on accumulating a pair-dependency value from a successor according to the above-described embodiments. For example, the BC calculation circuit 120 may accumulate the pair-dependency value in a direction from a farthest target node to the source node, for example, in a reverse direction.

According to one or more example embodiments, the BC calculation circuit 120 may calculate an accumulation coefficient for a successor included in the sequence set S. The accumulation coefficient may be defined as

$${\sum }_{w : v ∈ {P}_{s} ( w )} \frac{{σ}_{sv}}{{σ}_{sw}} \cdot ( p ( s ) p ( w ) + {δ}_{s , p} ( w ) )$$

in Equation 6. For example, the accumulation coefficient may be defined based on the product of the first pair-dependency value, the first port number PN1, and the second port number PN2, and the first shortest path number SPN1. For example, the accumulation coefficient for successor w may be obtained by multiplying a value, obtained by adding the product of p(s) that is the first port number PN1 and p(w) that is the second port number PN2 for a successor and δ_{s•,p}(w) that is a first pair-dependency value for successor w, by a ratio of σ_{sw}(v, {v, w})=σₛᵥ that is the first shortest path number SPN1 for node v and σ_{sw}(v, {v, w})=σₛᵥ that is the first shortest path number SPN1 for successor w.

The BC calculation circuit 120 may calculate a coefficient defined as

$$\frac{1}{{σ}_{sw}} \cdot ( p ( s ) p ( w ) + {δ}_{s , p} ( w ) )$$

for successor w. Then, the BC calculation circuit 120 may calculate

$${\sum }_{w : v ∈ {P}_{s} ( w )} \frac{{σ}_{sv}}{{σ}_{sw}} \cdot ( p ( s ) p ( w ) + {δ}_{s , p} ( w ) )$$

for arbitrary node v included in the predecessor set P for current successor w. The defined σ_{sw}(v, {v, w})=σₛᵥ and σ_{sw}(v, {v, w})=σₛᵥ are variables included in the first shortest path number SPN1 and the second shortest path number SPN2, and detailed definitions thereof are the same as described above. Also, p(s) may correspond to the first port number PN1, and p(w) may correspond to the second port number PN2 (when the target node is successor w).

The BC calculation circuit 120 may calculate a BC value for a link (hereinafter referred to as a fourth BC value BC4) by cumulatively summing the calculated accumulation coefficient to the BC value for the link. For example, the BC calculation circuit 120 may update and calculate the fourth BC value BC4 based on cumulatively summing an accumulation coefficient for one or more predecessors for a successor.

The BC calculation circuit 120 may calculate the fourth BC value BC4 for a plurality of links of all successors while changing the successor in a direction toward the source node. The following description may be provided based on an equation. The BC calculation circuit 120 may perform BC{v, w}+=c on an arbitrary node v of the predecessor set P. Here, BC{v, w} is the fourth BC value BC4 and c is the accumulation coefficient. The BC calculation circuit 120 may perform the summation of the fourth BC value BC4 on the sequence set S.

In addition, the BC calculation circuit 120 may update the first pair-dependency value based on cumulatively summing an accumulation coefficient for one or more predecessors of the successor.

The BC calculation circuit 120 may determine whether the successor is the source node. When the successor is not the source node, the BC calculation circuit 120 may calculate the sum of the product of the updated first pair-dependency value and the first port number PN1 and the second port number PN2. The BC calculation circuit 120 may calculate the first BC value BC1 based on accumulating the sum while changing the successor in a direction toward the source node.

The following description may be provided based on an equation. The BC calculation circuit 120 may update a first pair-dependency value δ(v) for nodes v included in the predecessor set P for the successor w by performing δ(v)+=c. Then, the BC calculation circuit 120 may calculate the first BC value BC1 for successor w in a case, in which the successor is not the source node, by performing BC(w)+=δ(w)+p(s)*p(w), where δ(w) is a pair-dependency value for the successor w after the update based on the accumulation of the accumulation coefficient is completed.

The electronic device 100B according to the above-described embodiments may perform a process of calculating the first pair-dependency value for all node pairs through the process of accumulating the pair-dependency value from the successor. As a result, the BC value in the node-port structure may be calculated without the time complexity of calculation.

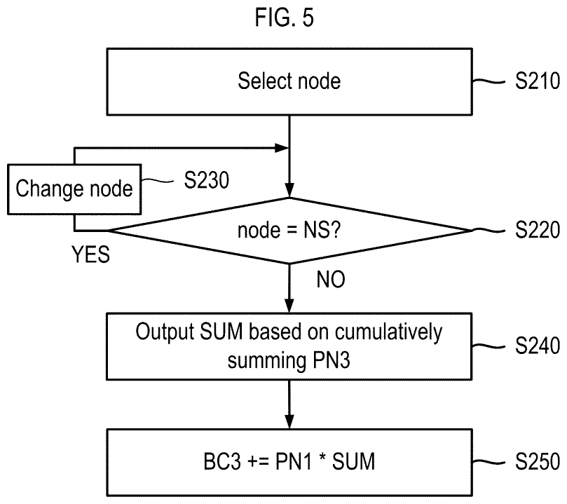

FIG. 5 is a flowchart illustrating a method of calculating a BC value of an electronic device according to one or more example embodiments.

Referring to FIG. 5, in operation S210, the electronic device may select an arbitrary node included in a sequence set S. In operation S220, the electronic device may check whether the selected node is a source node NS. When the selected node is the source node NS, the flow proceeds to operation S230 in which the electronic device may change the node, and may repeatedly perform S210 to S220.

When the selected node is not the source node NS, the flow proceeds to operation S240 in which the electronic device may output a sum port number SUM based on cumulatively summing the third port number PN3 for the remaining nodes.

In operation S250, the electronic device may calculate a third BC value BC3 for the source node NS based on cumulatively summing the product of the sum port number SUM, output in operation S240, and the first port number PN1.

Through the above-described operation method of the electronic device, the BC value for the source node may be calculated by taking the fact that an actual departure point in the node-port structure is a port into consideration for the BC calculation.

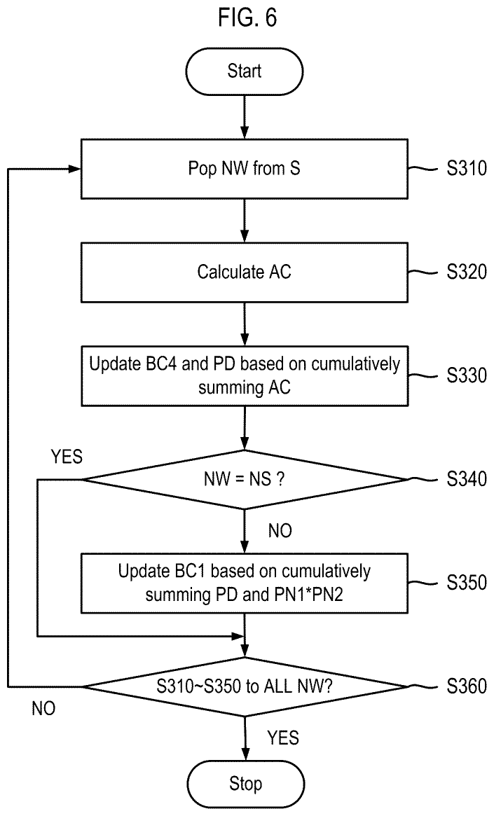

FIG. 6 is a flowchart illustrating a method of calculating a BC value of an electronic device according to one or more example embodiments.

Referring to FIG. 6, in operation S310, the electronic device may pop a successor NW from a sequence set S.

In operation S320, the electronic device may calculate an accumulation coefficient AC for the successor NW included in the sequence set S. For example, the calculation of the accumulation coefficient AC may be performed based on Equation 6.

In operation S330, the electronic device may update a fourth BC value BC4 and a pair-dependency value PD for a plurality of links based on cumulatively summing the accumulation coefficient AC for one or more predecessors of the successor NW. The updated pair-dependency value PD may be a first pair-dependency value of the predecessor for the successor NW.

In operation S340, the electronic device may determine whether the successor NW is a source node NS. When the successor NW is not the source node NS, the flow proceeds to operation S350 in which the electronic device may calculate the sum of the product of the updated first pair-dependency value PD and a first port number PN1 and a second port number PN2. The electronic device may update and calculate a first BC value BC1 based on accumulating the calculated sum while changing the successor NW in a direction toward the source node NS. For example, the electronic device may update the first BC value BC1 by cumulatively summing the product of the updated first pair-dependency value and the first port number PN1 and the second port number PN2.

In operation S360, the electronic device determines whether operations S310 to S350 have been performed on all successors NW. When a successor remain, the electronic device may repeatedly perform operations S310 to S350 on the remaining successor NW.

Through the above-described operation method of the electronic device, time complexity may be reduced compared to summing pair-dependency values for all node pairs.

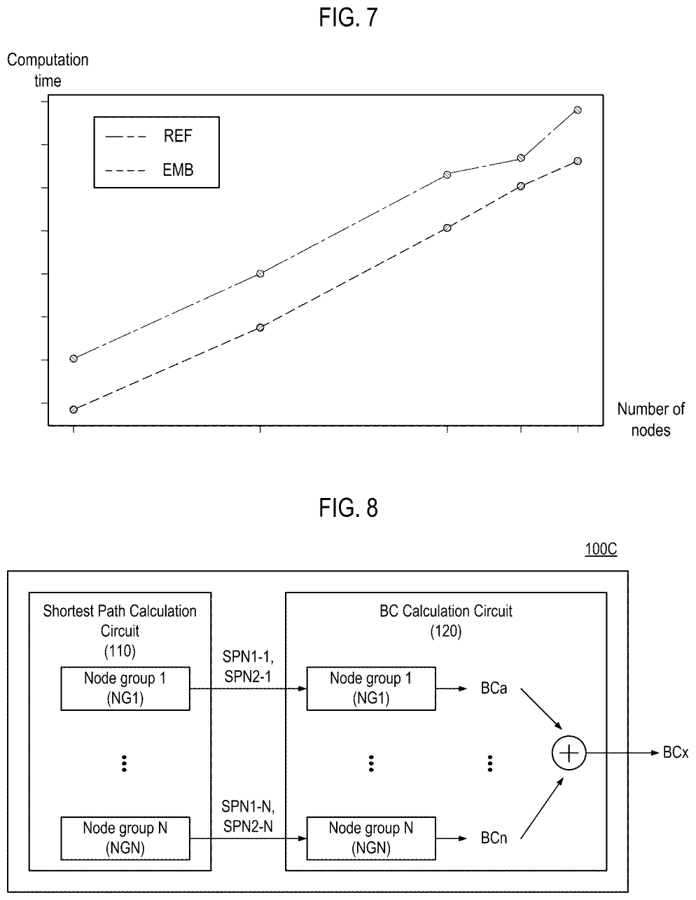

FIG. 7 is a graph illustrating a comparison between computation times of BC calculation according to one or more example embodiments.

In FIG. 7, computation times for nodes of a comparison target algorithm REF and a BC calculation operation EMB according to one or more example embodiments are illustrated, respectively. The comparison target algorithm REF is a Brandes algorithm. The BC calculation operation EMB according to one or more example embodiments is performed based on Equation 6.

As illustrated in the drawing, the BC calculation operation EMB according to one or more example embodiments may exhibit calculation time of a lower BC value than the comparison target algorithm REF regardless of the number of nodes (for example, for all node number count ranges). This is because the Brandes algorithm considers a port as an additional node in a node-port structure, and therefore, a total calculation time increases compared to the BC calculation operation EMB according to one or more example embodiments.

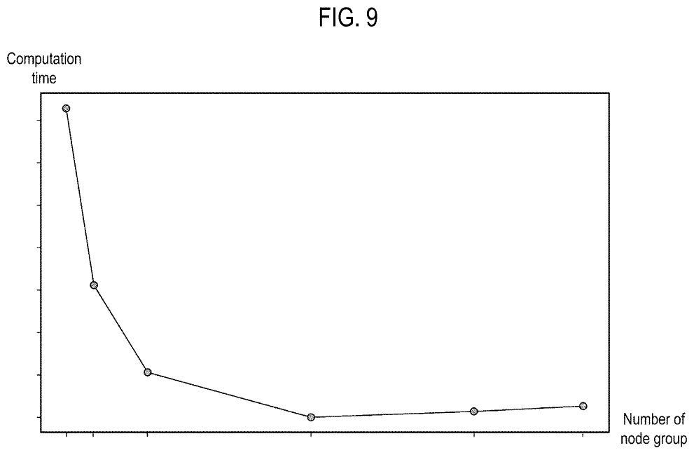

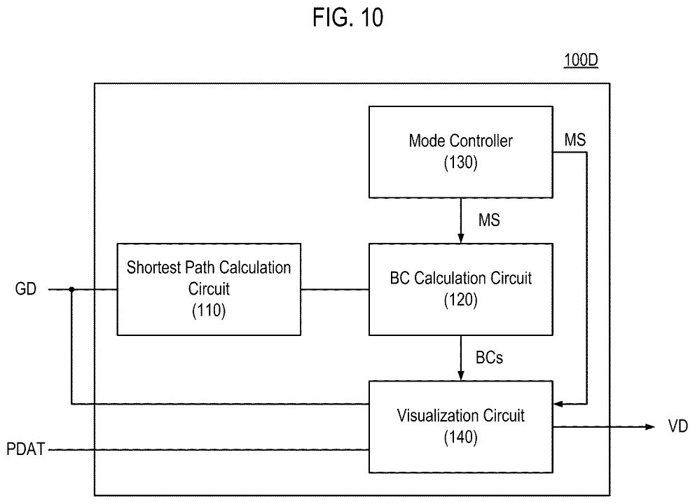

FIG. 8 is a block diagram of an electronic device according to one or more example embodiments, and FIG. 9 is a diagram illustrating a computation time of the electronic device of FIG. 8.

Referring to FIG. 8, an electronic device 100C according to one or more example embodiments may parallelize and perform the above-described operations. For example, the electronic device 100C may calculate a first BC value BC1 in parallel for each of a plurality of node groups, each formed by grouping a plurality of nodes. According to one or more example embodiments, the number N of node groups may be a value obtained by dividing the total number of all nodes, included in a node-port structure, by M (where M is a positive integer).

A shortest path calculation circuit 110 may output a first shortest path number SPN1 and a second shortest path number SPN2 from each node group. For example, the shortest path calculation circuit 110 may output a 1-1-th shortest path number SPN1-1 and a 2-1-th shortest path number SPN2-1 for a first node group NG1, and output a 1-N-th shortest path number SPN1-N and a 2-N-th shortest path number SPN2-N for an Nth node group NGN. According to one or more example embodiments, the shortest path calculation circuit 110 may also output a sequence set and a predecessor set to each node group along with the shortest path number.

Similarly, the BC calculation circuit 120 may calculate and output a BC value from each node group. For example, the BC calculation circuit 120 may output BCa for the first node group NG1, and output BCn for the Nth node group NGN.

Then, the BC calculation circuit 120 may add up all calculated BC values and finally output a BC value BCx for an entire node-port structure.

From FIG. 9, it can be seen that the calculation time decreases as the number N of node groups increases. For example, N may be set to a larger value to further reduce the calculation time. As a result, the electronic device according to the above-described embodiments may parallelize both shortest path calculation and BC calculation. The parallelization may reduce the time required for BC calculation.

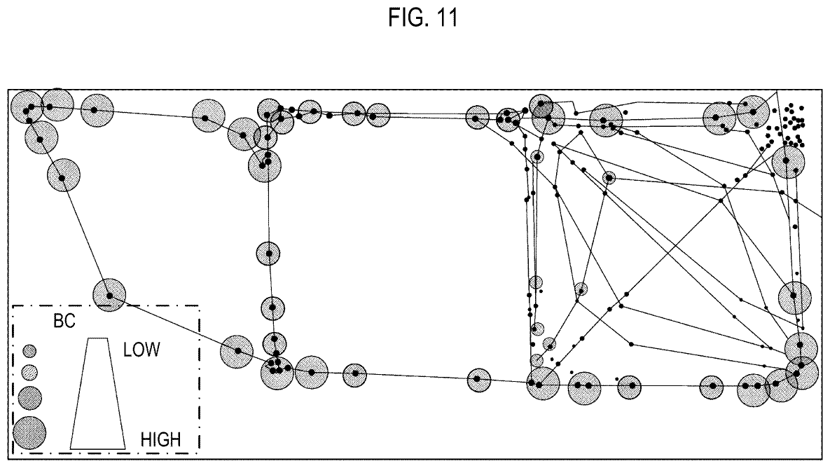

FIG. 10 is a block diagram of an electronic device according to one or more example embodiments.

Referring to FIG. 10, an electronic device 100D according to one or more example embodiments may include a mode controller 130 and a visualization circuit 140, in addition to the above-described shortest path calculation circuit 110 and BC calculation circuit 120.

According to one or more example embodiments, the shortest path calculation circuit 110 may calculate a shortest path number based on graph data GD, and the BC calculation circuit 120 may output BC values. For example, the BC values output through the BC calculation circuit 120 may include the above-described first to fourth BC values.

The mode controller 130 may select one of the following modes: a first mode, in which the second BC value is calculated based on node data and link data, and a second mode in which the first BC value, the third BC value, and the fourth BC value are calculated based on the node data, the link data, and port data PDAT. For example, when calculation of BC values for a node structure is required, the mode controller 130 may select the first mode. Alternatively, when calculation of BC values for a node-port structure is required, the mode controller 130 may select the second mode.

When a mode is selected by the mode controller 130 according to one or more example embodiments, the BC calculation circuit 120 may operate according to the selected mode. For example, in the first mode, the BC calculation circuit 120 may calculate the BC value for a node structure. Alternatively, in the second mode, the BC calculation circuit 120 may calculate the BC value for a node-port structure. The mode controller 130 may provide a mode select signal MS, indicating the selected mode, to the BC calculation circuit 120.

The visualization circuit 140 may output visualization data VD from the graph data GD, the port data PDAT, and the BC values calculated by the BC calculation circuit 120. For example, the graph data GD may include node data for a plurality of nodes and link data for a plurality of links. The node data may include identifier information on each node, and the graph data GD may include identifier data of each port as data on the plurality of ports. Additionally, the link data may include data on a source node, a target node, and a normalized distance of the path.

The visualization circuit 140 may visualize a BC value corresponding to each mode to output visualization data VD to a plurality of nodes and a plurality of links. For example, the visualization circuit 140 may visualize the second BC value (and a BC value for a link in the node structure, or the like) in the first mode. Alternatively, the visualization circuit 140 may visualize the first BC value (and the third BC value, the fourth BC value, or the like) in the second mode.

Alternatively, according to one or more example embodiments, the mode controller 130 may select a third mode in which the visualization circuit 140 does not visualize a BC value, but outputs only a layout for a node structure or a node-port structure. The mode controller 130 may transmit a mode select signal MS, indicating the third mode, to the visualization circuit 140, and the visualization circuit 140 may output visualization data VD representing a simple layout in which the BC value is not reflected.

According to one or more example embodiments, the visualization circuit 140 may perform a force-directed algorithm to output visualization data VD. The force-directed algorithm is an algorithm for visualizing a graph based on forces applied by nodes in the node structure or the node-port structure. However, when a size of the graph is large, the nodes and links in the visualization data output through the force-directed algorithm may be tangled.

According to one or more example embodiments, the visualization circuit 140 may take grid-force into consideration when performing the force-directed algorithm. The visualization circuit 140 may allow nodes of the graph to be aligned in a grid-like structure through the grid-force. The grid-force may act on each node, pulling each node toward a closest grid point.

Through the electronic devices 100D according to the above-described embodiments, the node structure or the node-port structure based on the calculated BC value may be visualized. As a result, structurally vulnerable sections may be identified through visualization data.

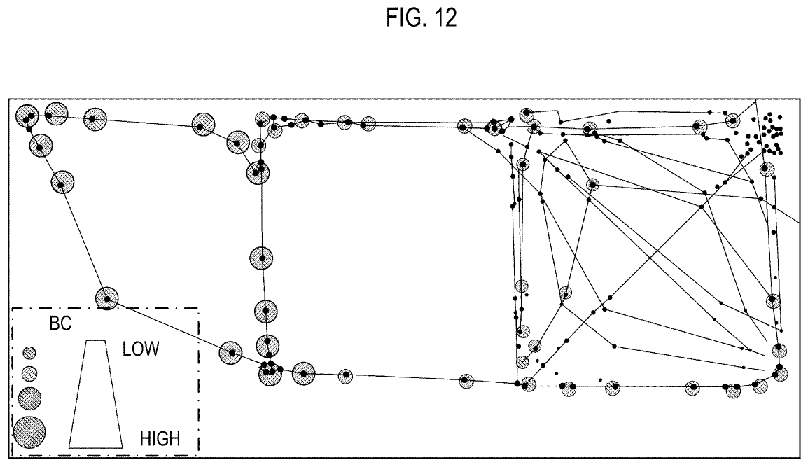

FIG. 11 is a diagram illustrating visualization data considering only a node for a node-port structure according to one or more example embodiments, and FIG. 12 is a diagram illustrating visualization data considering both a node and a port for a node-port structure according to one or more example embodiments.

FIGS. 11 and 12 include bridge links in the node-port structure.

Referring to FIG. 11, when only a node is taken into consideration for a node-port structure (for example, when visualized according to a BC value calculated based on Equation 1), a BC value in a bridge section in the node-port structure is high. However, there are not many ports in the bridge section, and thus, the bridge section is less likely to be vulnerable to congestion. For example, when the BC value is calculated in consideration of only a node, it may be difficult to reflect a congestion situation in an actual node-port structure in visualization data.

Referring to FIG. 12, when a port is considered together in a node-port structure (for example, when visualized according to a BC value calculated based on Equation 2), a BC value in a bridge portion is lower than in FIG. 11. Accordingly, the visualization data according to FIG. 12 may have a BC value closer to an actual condition of the node-port structure.

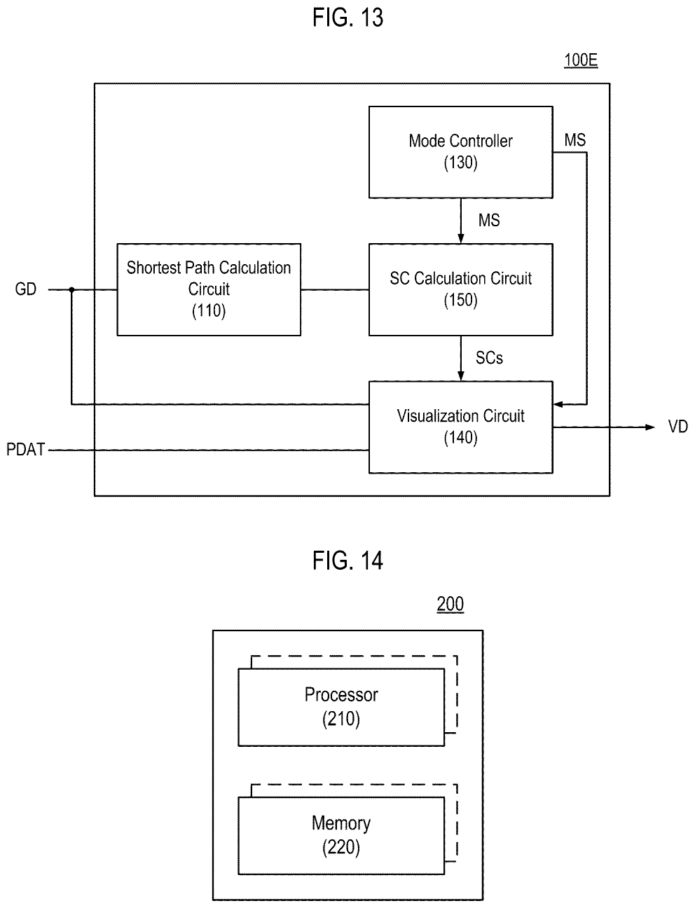

FIG. 13 is a block diagram of an electronic device according to one or more example embodiments. Hereinafter, redundant descriptions will be omitted to avoid repetition.

Referring to FIG. 13, an electronic device 100E according to one or more example embodiments may include an SC calculation circuit 150 configured to calculate stress centrality (SC), in addition to a shortest path calculation circuit 110 configured to calculate a shortest path number, a mode controller 130, and a visualization circuit 140.

The mode controller 130 may select one of the following modes: a first mode in which a node structure is considered, a second mode in which a node-port structure is considered, and a third mode in which only a layout is output, and may provide a mode select signal MS, indicating the selected mode, to the SC calculation circuit 150 and the visualization circuit 140.

The SC calculation circuit 150 may calculate an SC value for the node structure in the first mode or an SC value for the node-port structure in the second mode, and may provide the calculated SC values SCs to the visualization circuit 140. According to one or more example embodiments, the SC calculation circuit 150 may calculate an SC value for an arbitrary node by summing all first shortest path numbers calculated by the shortest path calculation circuit 110.

The visualization circuit 140 may visualize the SC values calculated by the SC calculation circuit 150 and output visualization data VD.

The electronic devices 100E according to the above-described embodiments may visualize and output an SC value, allowing visualization data to help check congested sections of a railway network and evaluate robustness of the railway network.

FIG. 14 is a block diagram of an electronic device according to one or more example embodiments.

Referring to FIG. 14, an electronic device 200 according to one or more example embodiments may include one or more processors 210 and one or more memories 220.

The one or more processors 210 may be connected to the one or more memories 220 to control the one or more memories 220, and may execute at least one instruction, stored in the one or more memories 220, to implement descriptions, functions, procedures, proposals, methods, and/or operational flowcharts of the disclosure. In addition, the one or more processors 210 may provide operations according to various embodiments based on the instructions stored in the one or more memories 220. In addition, the one or more processors 210 may process information, stored in the one or more memories 220, to generate data.

According to one or more example embodiments, each of the one or more processors 210 may be an additional processor or a core included in a multi-core processor. The multi-core processor may be a single computing component including two or more independent processors, and each of the processors (or cores) may read and execute instructions.

According to one or more example embodiments, when the one or more processors 210 are included in plural or implemented as a multi-core processor according to one or more example embodiments, the one or more processors 210 may perform parallelization according to the above-described embodiments. For example, each of the one or more processors 210 may perform shortest path calculation and/or BC value calculation for a plurality of node groups.

According to one or more example embodiments, the one or more processors 210 may include one or more processing elements configured to process elements that may be symmetric or asymmetric. A processing element may refer to hardware or logic to support a software thread. For example, hardware processing elements may include a thread unit, a thread slot, a thread, a process unit, a context, a context unit, a logical processor, a hardware thread, or a core. For example, a processing element may refer to any hardware capable of being independently associated with code, such as a software thread, operating system, application, or other code.

According to one or more example embodiments, the one or more processors 210 may be implemented as a general-purpose processor, a specific-purpose processor, an application processor (AP), or the like. For example, the one or more processors 210 may be implemented as an operational processor (for example, a central processing unit (CPU) or a graphics processing unit (GPU)) including a specific-purpose logic circuit (for example, a field programmable gate array (FPGA) or application specific integrated chips (ASICs)), but example embodiments are not limited thereto.

The one or more memories 220 may be connected to the one or more processors 210, and may store various information related to the operation of the one or more processors 210. For example, the one or more memories 220 may a software code for performing a portion or all of the processes or threads controlled by the one or more processors 210, or performing descriptions, functions, procedures, proposals, methods, and/or operational flowcharts of the disclosure. For example, the software code may be implemented in a procedural or object-oriented programming language or in assembly or machine code. Alternatively, the software code may be implemented in a declarative programming language. Additionally, example embodiments are not limited to any specific programming language.

The one or more processors 210 may execute at least one instruction, stored in the one or more memories 220, to perform the above-described operations and functions according to the one or more example embodiments of FIGS. 1 to 13. According to one or more example embodiments, the one or more processors 10 may output a first shortest path number and a second shortest path number based on performing the shortest path calculation algorithm on a plurality of nodes and a plurality of links. The one or more processors 210 may calculate a first BC value for the plurality of nodes based on summing first pair-dependency values for each pair of a source node and a target node among the plurality of nodes.

The electronic device 200 according to the above-described embodiments may calculate the BC value in consideration of ports in the node-port structure as well as calculate the BC value in the node structure.

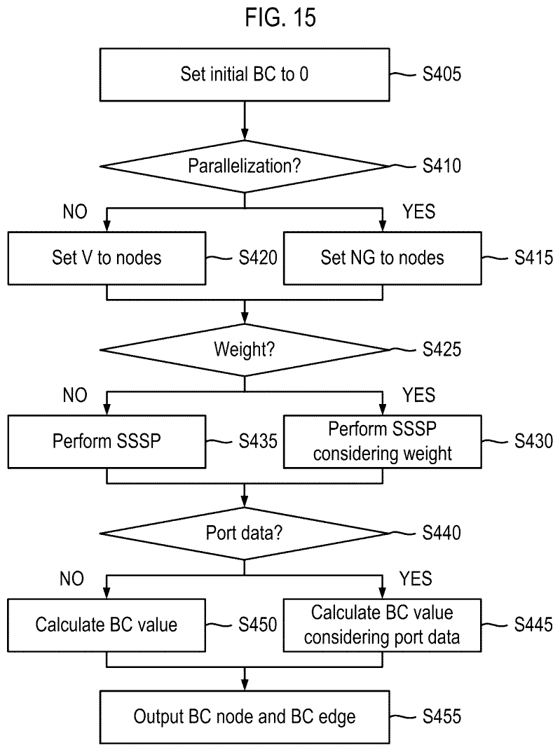

FIG. 15 is a flowchart illustrating a method of operating an electronic device according to one or more example embodiments.

Referring to FIG. 15, in operation S405, the electronic device may set an initial BC value to 0. Both the BC value for a node and the BC value for a link may be set to 0.

In operation S410, the electronic device may determine whether to perform parallelization.

When the parallelization is possible, the flow proceeds to operation S415 in which the electronic device may set a plurality of node groups NG as target nodes. When the parallelization is not possible, the flow proceeds to operation S420 in which the electronic device may set all nodes in a node set V as target nodes.

In operation S425, the electronic device may determine whether there is a weight for a node in the node set V. The weight is a value assigned to each link, and may represent cost or distance of a link connecting two nodes to each other. For example, the weight is a value representing strength or importance of a relationship represented by the link.

When there is a weight, the flow proceeds to operation S430 in which the electronic device may perform an SSSP algorithm based on the weight. When there is no weight, the flow proceeds to operation S435 in which the electronic device may perform the SSSP algorithm without weight. According to one or more example embodiments, when there is a weight, the electronic device may perform a Dijkstra algorithm on a source node. When there is no weight, the electronic device may perform a BFS algorithm on the source node.

Through the SSSP algorithm, the electronic device may output a sequence set, a predecessor set, and shortest path numbers.

In operation S440, the electronic device may determine whether there is port data.

When there is port data, the flow proceeds to operation S445 in which the electronic device may calculate a BC value considering the port data according to the above-described embodiments. For example, the electronic device may calculate a BC value for a node-port structure. For example, the electronic device may calculate a first BC value, a third BC value, and a fourth BC value.

When there is no port data, the flow proceeds to operation S450 in which the electronic device may calculate a BC value without considering the port data. For example, the electronic device may calculate a second BC value.

In operation S455, the electronic device may divide the calculated BC value into a BC value for a node and a BC value for a link and output the divided BC values.

Through the described operation method, the electronic device may perform parallelization to increase calculation speed, and/or calculate a BC value for a node-port structure when there is port data.

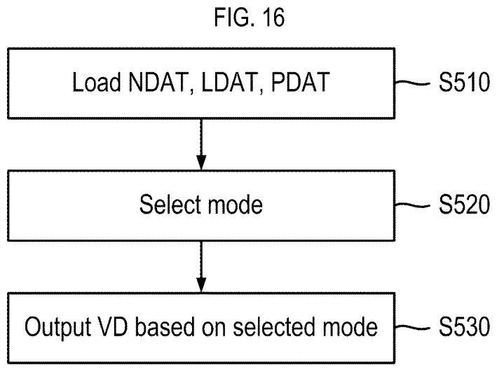

FIG. 16 is a flowchart illustrating a method for visualizing an electronic device according to one or more example embodiments.

Referring to FIG. 16, in operation S510, the electronic device may load at least one of node data NDAT, link data LDAT, and port data PDAT from at least one memory.

In operation S520, the electronic device may select one of the following modes: a first mode in which the electronic device calculates a second BC value based on node data NDAT and link data LDAT, or a second mode in which the electronic device calculates a first BC value based on node data NDAT, link data LDAT, and port data PDAT. According to one or more example embodiments, the electronic device may also select a third mode in which the electronic device outputs a layout.

According to one or more example embodiments, the electronic device may load node data NDAT and link data LDAT from at least one memory based on selecting the first mode. Alternatively, the electronic device may load node data NDAT, link data LDAT, and port data PDAT from at least one memory based on selecting the second mode.

In operation S530, the electronic device may visualize the first BC value or the second BC value for a plurality of nodes and a plurality of links to correspond to the selected mode, and may output visualization data VD.

As set forth above, according to one or more example embodiments, an electronic device for calculating betweenness centrality (BC) considering a port in a node-port structure and an operation method of the electronic device may be provided.

While one or more example embodiments have been shown and described above, it will be apparent to those skilled in the art that modifications and variations could be made without departing from the scope of the disclosure as defined by the appended claims and their equivalents.

What is claimed is:

1. An electronic device comprising:
at least one memory configured to store at least one instruction; and
at least one processor configured to execute the at least one instruction,
wherein the at least one processor, by executing the at least one instruction, is configured to:
output a first shortest path number, defined by a source node, a pass node, and a target node among a plurality of nodes to which a plurality of ports are connected, and a second shortest path number, defined by the source node and the target node, based on performing a shortest path calculation algorithm on the plurality of nodes and a plurality of links connecting the plurality of nodes; and
calculate a first betweenness centrality (BC) value for the plurality of nodes based on summing first pair-dependency values for respective pairs of the source node and the target node among the plurality of nodes, and
wherein a first pair-dependency value is defined as a product of a second pair-dependency value defined as a ratio of the first shortest path number to the second shortest path number, a first port number defined as a number of ports connected to the source node among the plurality of ports, and a second port number defined as a number of ports connected to the target node among the plurality of ports.

2. The electronic device of claim 1, wherein each of the plurality of nodes includes a sensor configured to sense an overhead hoist transport (OHT) device, and
wherein each of the plurality of ports is configured to accommodate a container transported through the OHT device.

3. The electronic device of claim 1, wherein the at least one processor, by executing the at least one instruction, is further configured to:
determine whether there is port data on the plurality of ports; and
calculate a second BC value for the plurality of nodes based on summing second pair-dependency values for the respective pairs of the source node and the target node among the plurality of nodes, when there is no port data on the plurality of ports.

4. The electronic device of claim 1, wherein the at least one processor, by executing the at least one instruction, is further configured to calculate, in parallel, the first BC value for each of a plurality of node groups, each node group being formed by grouping the plurality of nodes.

5. The electronic device of claim 1, wherein the at least one processor, by executing the at least one instruction, is further configured to:
output a sum port number for remaining nodes except for the source node among the plurality of nodes, based on cumulatively summing a third port number defined as a number of ports connected to the remaining node; and
calculate a third BC value for the source node, based on cumulatively summing a product of the sum port number and the first port number for the source node.

6. The electronic device of claim 1, wherein the at least one processor, by executing the at least one instruction, is further configured to:
output a sequence set defined as a node sequence for the target node from the source node based on performing the shortest path calculation algorithm;
calculate an accumulation coefficient for a successor node included in the sequence set; and
calculate a fourth BC value for the plurality of links based on cumulatively summing accumulation coefficients for one or more predecessor nodes with respect to the successor node.

7. The electronic device of claim 6, wherein the at least one processor, by executing the at least one instruction, is further configured to:
update the first pair-dependency value based on cumulatively summing the accumulation coefficient for the one or more predecessor nodes for the successor node;
determine whether the successor node is the source node;
calculate a sum of the updated first pair-dependency value and a sum of the first port number and the second port number when the successor node is not the source node; and
calculate the first BC value based on accumulating the sum while changing the successor node in a direction toward the source node.

8. The electronic device of claim 1, wherein the at least one processor, by executing the at least one instruction, is further configured to:
load, from the at least one memory, at least two of node data on the plurality of nodes, link data on the plurality of links, and port data on the plurality of ports;
select either one of a first mode, in which a second BC value is calculated based on the node data and the link data, and a second mode, in which the first BC value is calculated based on the node data, the link data, and the port data; and
control to visualize the first BC value or the second BC value for the plurality of nodes and the plurality of links to output visualization data.

9. The electronic device of claim 8, wherein the at least one processor, by executing the at least one instruction, is further configured to:
load the node data and the link data from the at least one memory based on the first mode being selected; and
load the node data, the link data, and the port data from the at least one memory based on the second mode being selected.

10. The electronic device of claim 6, wherein the accumulation coefficient is defined based on the first pair-dependency value, a product of the first port number and the second port number, and the first shortest path number.

11. A method of operating an electronic device, the method comprising:
outputting a first shortest path number defined as a source node, a pass node, and a target node, among a plurality of nodes to which a plurality of ports are connected, and a second shortest path number defined based on the source node and the target node, based on performing a shortest path calculation algorithm on the plurality of nodes and a plurality of links connecting the plurality of nodes; and
calculating a first betweenness centrality (BC) value for the plurality of nodes based on summing first pair-dependency values for respective pairs of the source node and the target node among the plurality of nodes, a first pair-dependency value being defined as a product of a second pair-dependency value defined as a ratio of the first shortest path number to the second shortest path number, a first port number defined as a number of ports connected to the source node among the plurality of ports, and a second port number defined as a number of ports connected to the target node among the plurality of ports.

12. The method of claim 11, further comprising:
determining whether there is port data on the plurality of ports; and
calculating a second BC value for the plurality of nodes based on summing second pair-dependency values for the respective pairs of the source node and the target node among the plurality of nodes when there is no port data on the plurality of ports.

13. The method of claim 11, further comprising:
outputting a sum port number for remaining nodes except for the source node among the plurality of nodes, based on cumulatively summing a third port number defined as a number of ports connected to the remaining nodes; and
calculating a third BC value for the source node based on cumulatively summing a product of the sum port number and the first port number for the source node.

14. The method of claim 11, further comprising:
outputting a sequence set defined as a node sequence for the target node from the source node, based on performing the shortest path calculation algorithm;
calculating an accumulation coefficient for a successor node included in the sequence set; and
calculating a fourth BC value for the plurality of links based on cumulatively summing the accumulation coefficient for one or more predecessor nodes for the successor node.

15. The method of claim 14, further comprising:
updating the first pair-dependency value based on accumulating the accumulation coefficient for the one or more predecessor nodes for the successor node;
determining whether the successor node is the source node;
calculating a sum of the updated first pair-dependency value and a product of the first port number and the second port number when the successor node is not the source node; and
calculating the first BC value based on accumulating the sum while changing the successor node in a direction toward the source node.

16. The method of claim 11, further comprising:
loading at least two of node data on the plurality of nodes, link data on the plurality of links, and port data on the plurality of ports;
selecting either one of a first mode for calculating a second BC value based on the node data and the link data and a second mode for calculating the first BC value based on the node data, the link data, and the port data; and
controlling to visualize the first BC value or the second BC value for the plurality of nodes and the plurality of links to output visualization data.

17. The method of claim 14, wherein
the accumulation coefficient is defined based on the first pair-dependency value, a product of the first port number and the second port number, and the first shortest path number.

18. An electronic device comprising:
a shortest path calculation circuit configured to output a first shortest path number defined as a source node, a pass node, and a target node, among a plurality of nodes to which a plurality of ports are connected, and a second shortest path number defined based on the source node and the target node, based on performing a shortest path calculation algorithm on the plurality of nodes and a plurality of links connecting the plurality of nodes; and
a BC calculation circuit configured to calculate a first betweenness centrality (BC) value for the plurality of nodes based on summing first pair-dependency values for respective pairs of the source node and the target node among the plurality of nodes, a first pair-dependency value being defined as a product of a second pair-dependency value defined as a ratio of the first shortest path number to the second shortest path number, a first port number defined as a number of ports connected to the source node among the plurality of ports, and a second port number defined as a number of ports connected to the target node among the plurality of ports.

19. The electronic device of claim 18, further comprising:
a mode controller configured to select either one of a first mode, in which a second BC value is calculated based on node data on the plurality of nodes and link data on the plurality of links, and a second mode, in which the first BC value is calculated based on the node data, the link data, and port data on the plurality of ports.

20. The electronic device of claim 19, further comprising:
a visualization circuit configured to visualize the first BC value or the second BC value to output visualization data for the plurality of nodes and the plurality of links.
